(19) United States
(12) Patent Application Publication
(10) Pub. No.: US 2009/0079062 A1
(43) Pub. Date: Mar. 26, 2009

(54) SEMICONDUCTOR PACKAGE AND ELECTRONIC DEVICE

(75) Inventor: Masateru KOIDE, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/325,679

(22) Filed: Dec. 1, 2008

Related U.S. Application Data
(63) Continuation of application No. PCT/JP2006/311423, filed on Jun. 7, 2006.

(51) Int. Cl. H01L 23/36

(52) U.S. Cl. 257/712; 257/E23.101

(57) ABSTRACT

A semiconductor package is provided. The semiconductor package includes: a package substrate on which a semiconductor device is mounted; a heat spreader at least bonded to a surface of the semiconductor device and having a thermal expansion coefficient value equal to or less than a thermal expansion coefficient value of the package substrate; a metal layer provided on a bonding face of the heat spreader bonded to the semiconductor device; and a solder layer formed between the metal layer and semiconductor device, and bonding the heat spreader to the semiconductor device.

### CROSS-REFERENCE TO RELATED APPLICATIONS

This application is a continuation application and is based upon the International Application No. PCT/JP2006/311423, filed on Jun. 7, 2006, the entire contents of which are incorporated herein by reference.

### FIELD

The present invention relates to a semiconductor package.

### BACKGROUND ART

In recent years, as integration of semiconductor devices and speedup of their operation frequencies proceed, it becomes a key issue to dissipate the heat generated by semiconductor devices. What is performed for releasing the heat of a semiconductor device in general is to bond a part of the device package to the semiconductor device as a heat spreader for releasing heat.

Heat spreaders are stuck to semiconductor devices primarily. In such condition, a heat spreader serves to dissipate the heat generated by the semiconductor device per se, and protects the device. A heat spreader may seal a semiconductor device together with a package substrate on which the device is mounted.

Then, when the heat spreader is repeatedly exposed to the heat generated by the semiconductor device in action, a thermal stress is imposed on the package substrate because of the difference in thermal expansion rate between the package substrate and heat spreader. Therefore, when a semiconductor device undergoes alternately repeated activation and deactivation, an excessive load is put on e.g. a ball grid array (BGA) connecting between connection terminals of the device and package substrate, whereby the connection can be broken.

Likewise, the connection between a connection terminal of the package substrate and a connection terminal of a wiring board to which the package substrate is attached is in danger of being broken. Particularly, as to a type of equipment placed outdoors, the temperature inside the equipment can reach a very high temperature depending on the season. Therefore, a semiconductor package superior in the resistivity against heat generation by a semiconductor device is indispensable. Hence, it is preferable that heat spreaders not only be superior in heat conducting property, but also have a low thermal expansion rate.

For instance, in regard to the semiconductor package as described in Japanese Laid-open Patent Publication No. 2001-102475, the thermal expansion coefficient of an insulating substrate at a temperature of 40 to 150° C., which a semiconductor device is mounted on, is 8 to 20 ppm/° C., and the thermally conducting lid (heat spreader) is formed from a material having a thermal expansion coefficient lower than that of the insulating substrate of e.g. aluminum silicon carbide (AlSiC), Cu—W alloy, or Fe—Ni—Co alloy.

As for the semiconductor package therein disclosed, the heat spreader and semiconductor device are glued to each other with a thermally conducting resin. However, the heat conducting property of resin material is inferior to alloys used for heat spreaders. Therefore, to increase the efficiency of heat dissipation of semiconductor packages further, it is preferable to use a material having a better heat conducting property for bonding portions of a heat spreader and a semiconductor device.

Meanwhile, in the semiconductor integrated circuit device as disclosed in Japanese Laid-open Patent Publication H05-41471, a semiconductor chip and a heat-releasing cap formed from aluminum nitride (AlN) are bonded by solder superior in heat conducting property. For example, the thermal conductivity of silicon-enriched resin adhesive used to bond a heat spreader to a semiconductor device is about 0.5 W/mK. In contrast, some tin-lead based solder has a thermal conductivity of 31.5 W/mK, and some indium-silver based solder has a thermal conductivity of 48.2 W/mK. Using solder instead of resin-based adhesive in this way allows the heat generated by semiconductor to conduct to the heat spreader efficiently. In addition, the wettability of solder is improved by a bonding metal layer of titanium (Ti)/nickel(Ni)/Au provided on a surface of the cap.

The techniques as described above have improved the resistivity against heat generation by a semiconductor device and the heat-releasing capability. However, it is desired to develop a semiconductor package which can solve the two problems of improving the resistivity and heat-releasing capability in association with semiconductor devices whose quantities of heat generation are increasing with the progress of integration.

### SUMMARY

According to an aspect of the embodiment, a semiconductor package includes a package substrate on which a semiconductor device is mounted, a heat spreader at least bonded to a surface of the semiconductor device and having a thermal expansion coefficient value equal to or less than a thermal expansion coefficient value of the package substrate, a metal layer provided on a bonding face of the heat spreader bonded to the semiconductor device, and a solder layer formed between the metal layer and semiconductor device, and bonding the heat spreader to the semiconductor device.

Additional objects and advantageous of the embodiment will be set forth in part in the description which follows, and in part will be obvious from the description, or may be learned by practice of the invention. The object and advantageous of the invention will be realized and attained by means of the elements and combinations particularly pointed our in the appended claims.

It is to be understood that both the foregoing general description and the following detailed description are exemplary and explanatory only and are not restrictive of the invention, as claimed.

### BRIEF DESCRIPTION OF THE DRAWINGS

FIG. 1 is a schematic side sectional view illustrating an embodiment of the semiconductor package according to the invention; and

FIG. 2 is a diagram illustrating results of simulations according to a heat cycle test concerning a thermal stress applied to a solder layer.

### DESCRIPTION OF EMBODIMENT(S)

As stated above, semiconductor packages used for semiconductor devices, whose quantities of heat generation are increasing with the progress of integration, are required to be superior in the resistivity against heat generation by a semiconductor device and have a good heat-releasing capability. However, conventional semiconductor packages have not included the ones superior in both the resistivity and heat-releasing capability.

In contrast, with an embodiment of the semiconductor package according to the invention, the heat spreader is constructed of a material that is smaller in thermal expansion rate than the package substrate, e.g. aluminum silicon carbide (AlSiC), whereby the thermal stress imposed on the package substrate is reduced. Thus, the excellent resistivity against heat generation by a semiconductor device is achieved. Further, in the semiconductor package according to the invention, solder superior in thermal conductivity is used to bond the heat spreader to the semiconductor device, whereby the capability of releasing the heat generated by the semiconductor device is improved. Therefore, the semiconductor package according to the invention has a good resistivity against heat generation by a semiconductor device and is superior in the heat-releasing capability.

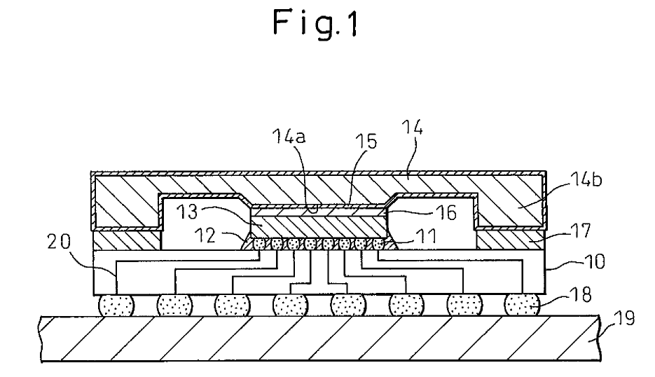

FIG. 1 illustrates a schematic side sectional view of an embodiment of the semiconductor package. The semiconductor package 1, which is an embodiment of the semiconductor package according to the invention, has: a package substrate 10 on which a semiconductor device 13 is mounted; and a heat spreader 14 which dissipates the heat generated by the semiconductor device 13.

The semiconductor device 13 is disposed on the package substrate 10. A ball grid array (BGA) 11 is formed between the semiconductor device 13 and package substrate 10. A connection terminal of the semiconductor device 13 is electrically connected through the BGA 11 to a metal wire 20 formed inside an insulator of the package substrate 10. Further, an underfill agent 12 consisting of a resin material is filled into the interstices between the package substrate 10 and semiconductor device 13, whereby BGA 11 is reinforced.

On the lower face of the package substrate 10, BGA 18 is formed to electrically connect with a wiring pattern formed on a circuit board 19. Further, the upper end of each metal wire 20 of the package substrate 10 is electrically connected to BGA 11, whereas the lower end is electrically connected to BGA 18. Thus, each connection terminal of the semiconductor device 13 is electrically connected with BOA 11, whereby the terminal is electrically connected to the circuit board 19 through the metal wire 20 and BGA 18. Incidentally, the package substrate 10 is an insulating substrate formed from a commonly used material of an organic resin such as glass-epoxy resin or glass-polyimide resin, ceramic or the like. In this embodiment, glass-epoxy resin having a thermal expansion coefficient of about 25 ppm/° C. is used as a material of the insulating substrate.

On the other hand, the heat spreader 14 is disposed over the semiconductor device 13. On a surface of the heat spreader 14, a metal layer 15 is formed. The heat spreader 14 has a bonding face 14a provided in a substantially central portion of its lower face; the bonding face is bonded to the upper face of the semiconductor device 13 through the metal layer 15 and solder layer 16. The heat spreader 14 dissipates the heat generated by the semiconductor device 13. In a peripheral portion of the heat spreader 14, a leg portion 14b is formed, where the heat spreader 14 is increased in thickness toward the package substrate 10. The leg portion 14b is glued to the package substrate 10 by an adhesive 17 so that the heat spreader 14 surrounds the semiconductor device 13, whereby the semiconductor device 13 is sealed. In this embodiment, the heat spreader 14 is formed from AlSiC having a thermal conductivity of about 150 W/mK, and a thermal expansion coefficient of about 11 ppm/° C. AlSiC used for the heat spreader 14 has a good heat conducting property like this. Therefore, the heat spreader 14 can dissipate the heat generated by the semiconductor device 13 efficiently. Further, the thermal expansion coefficient of AlSiC is equal to or less than that of the package substrate 10. On that account, the heat spreader can reduce the thermal stress which is applied to the package substrate 10 owing to the heat generated by the semiconductor device 13. In addition, the load of thermal stress imposed on LSI is reduced.

Now, in the light of the adhesion between the heat spreader 14 and metal layer 15, it is preferable that the surface roughness of the bonding face 14a of the heat spreader 14 is smaller. In this embodiment, the bonding face 14a of the heat spreader 14 is ground so that the surface roughness of the bonding face 14a becomes 1.6 μm or smaller on an arithmetic mean roughness basis (see JIS B 0601 and JIS B 0031).

The metal layer 15 formed on the surface of the heat spreader 14 makes it easier to solder the heat spreader 14 to the semiconductor device 13. The metal layer 15 is formed from a metal having a good wettability with respect to solder, e.g. gold or nickel. Also, the metal layer 15 may be formed by coating the surface of the heat spreader 14 with a metal plating. In this embodiment, the metal layer 15 is formed on the whole surface of the heat spreader 14 as illustrated in FIG. 1. However, the metal layer 15 may be formed only on the face 14a to be bonded to the semiconductor device 13.

The form, size and thickness of the heat spreader 14 may be adjusted appropriately according to the characteristics of the semiconductor package 1 and the specifications thereof. Particularly, the heat spreader 14 is formed from AlSiC, which is superior in the ease of fabrication and as such, the package can be manufactured at a low cost even when the heat spreader 14 is shaped into a relatively complicated form. In addition, as AlSiC is lighter in weight in comparison to copper and the like, the pressure produced by the weight of the heat spreader 14 on the semiconductor device 13 is relatively small. Consequently, the pressure applied to BGA 11 becomes small relatively, and therefore the amount of deformation of solder balls of BGA 11 becomes small, and the reliability of electrical connection between the semiconductor device 13 and package substrate 10 is increased.

For the solder layer 16 bonding the heat spreader 14 to the semiconductor device 13, a material that has a large thermal conductivity and is capable of offering a good strength of bonding between the semiconductor device 13 and metal layer 15 is used for the purpose of conducting the heat generated by the semiconductor device 13 to the heat spreader 14 efficiently. In this embodiment, indium-silver based solder is used for the solder layer 16. However, the solder layer 16 is not so limited. For example, tin-copper-silver based solder or tin-lead based solder may be used instead.

In addition, it is preferable that the solder layer 16 has a predetermined thickness or larger. The reason for this is to avoid that the change in temperature breaks the bond between the heat spreader 14 and semiconductor device 13 owing to the difference in thermal expansion rate between them. The solder layer 16 having an appropriate thickness can absorb distortion produced in the bonding portion of the semiconductor device 13 and heat spreader 14 owing to thermal expansion.

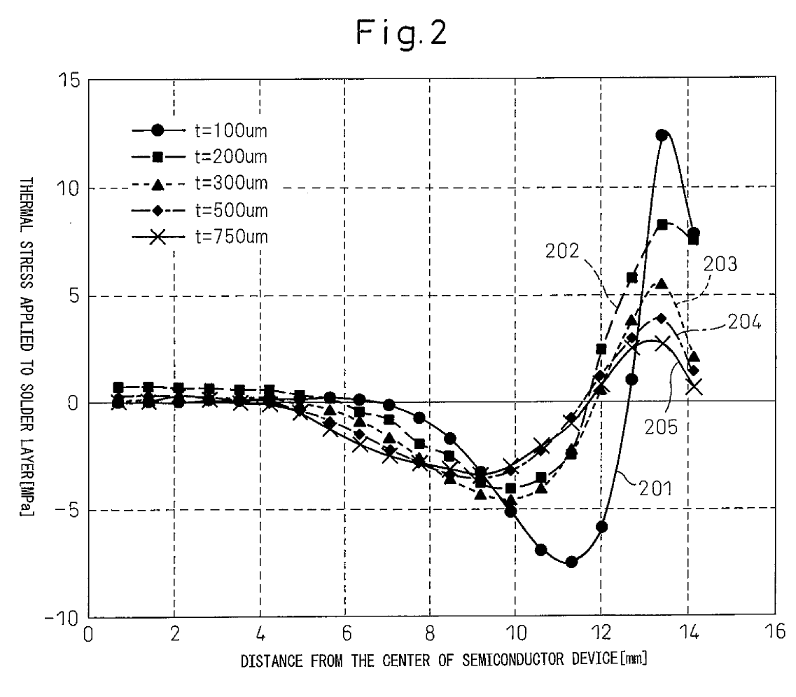

Further, it was found from a heat cycle test (−10 to +100° C./300 cycles) that the solder layer 16 was broken when the thermal stress was 5.04 MPa and larger. The thermal stress acting on the solder layer was simulated for the points in a range between the center of the solder layer 16 and a corner thereof according to the thickness t of the solder layer 16. FIG. 2 indicates results of the simulation (with the heat cycle of −10 to +100° C./300 cycles). In FIG. 2, the lateral axis represents the distance from a central portion of the semiconductor device 13, and the vertical axis represents the thermal stress applied to the solder layer 16. The curves 201, 202, 203, 204 and 205 indicate simulation results when the thickness of the solder layer 16 is 100, 200, 300, 500 and 750 μm, respectively. The thermal stress 5.04 MPa, which breaks the solder layer 16, corresponds the maximum thermal stress of the solder layer 16 with a thickness of 300 μm. Therefore, the lower limit of the thickness of the solder layer 16 is set to 400 μm leaving a leeway. To decrease the thermal resistance which the solder layer 16 has to 0.08° C./W or below, the upper limit of the thickness of the solder layer 16 is set to 460 μm. Hence, in this embodiment, the thickness of the solder layer 16 is set between 400 and 460 μm.

As described above, the semiconductor package 1, which is an embodiment of the semiconductor package according to the invention, attains both a good resistivity against heat generation by a semiconductor device and a good heat-releasing capability by forming a heat spreader from AlSiC with a small thermal expansion rate and soldering the heat spreader to a semiconductor device. In addition, the semiconductor package 1 can be suitably used for an electronic device placed outdoors because it is superior in the resistivity against heat generation by a semiconductor device.

Now, the description above is only for exemplification, the invention is not limited to it. For example, the material which can be used for the heat spreader is not limited to AlSiC. As an example of the alternative thereof, ScD (Skeleton cemented Diamond) (with a thermal conductivity of about 600 W/mK, and a thermal expansion coefficient of about 5 ppm/° C.), which is available from Skeleton Technologies AG, may be used for the heat spreader.

In addition, in each corner portion of the bonding face of the heat spreader to the semiconductor device, a protrusion may be provided. When such protrusions are provided, the bonding face of the heat spreader can be kept at a certain distance or larger from the semiconductor device. Further, other connection technologies including PGA (Pin Grid Array) may be used for the connection between the semiconductor device and package substrate and the connection between the package substrate and wiring board. As stated above, various arrangements may be made within a scope of the invention.

All examples and condition language recited herein are intended for pedagogical purpose to aid the reader in understanding the principles of the invention and the concepts contributed by the inventor to furthering the art, and are to be construed as being without limitation to such specifically recited examples and condition, nor does the organization of such examples in the specification relate to a showing of the superiority and inferiority of the invention. Although the embodiment(s) of the present inventions) has been described in detail, it should be understood that the various changes, substitutions, and alterations could be made hereto without departing from the spirit and scope of the invention.

What is claimed is:

1. A semiconductor package comprising:
a package substrate on which a semiconductor device is mounted;
a heat spreader at least bonded to a surface of the semiconductor device and having a thermal expansion coefficient value equal to or less than a thermal expansion coefficient value of the package substrate;
a metal layer provided on a bonding face of the heat spreader bonded to the semiconductor device; and,
a solder layer formed between the metal layer and semiconductor device, and bonding the heat spreader to the semiconductor device.

2. The semiconductor package of claim 1, wherein the heat spreader is formed from aluminum silicon carbide or diamond composite material.

3. The semiconductor package of claim 1, wherein a surface roughness of the bonding face of the heat spreader is no more than 1.6 μm on average.

4. The semiconductor package of claim 1, wherein a thickness of the solder layer is between 400 and 460 μm.

5. A semiconductor package comprising:
a package substrate on which a semiconductor device is mounted;
a heat spreader bonded to the semiconductor device, glued to the package substrate around the semiconductor device, and formed from one of aluminum silicon carbide and diamond composite material;
a metal layer provided on a bonding face of the heat spreader bonded to the semiconductor device; and,
a solder layer formed between the metal layer and semiconductor device, and bonding the heat spreader to the semiconductor device.

6. An electronic device comprising:
a circuit board with at least one electronic circuit element;
a semiconductor device; and,
a semiconductor package mounted on the circuit board, and containing the semiconductor device, the semiconductor package having
a package substrate which the semiconductor device is mounted on, and which electrically connects a connection terminal of the semiconductor device with a wire provided on the circuit board,
a heat spreader at least bonded to a surface of the semiconductor device, and having a thermal expansion coefficient value equal to or less than a thermal expansion coefficient value of the package substrate,
a metal layer provided on a bonding face of the heat spreader bonded to the semiconductor device, and,
a solder layer formed between the metal layer and semiconductor device and bonding the heat spreader to the semiconductor device.
